(19) United States
(12) Patent Application Publication
(10) Pub. No.: US 2019/0322576 A1
(43) Pub. Date: Oct. 24, 2019

(54) SUBSTRATE COATED WITH A LOW-EMISSIVITY COATING

(71) Applicant: SAINT-GOBAIN GLASS FRANCE, Courbevoie (FR)

(72) Inventors: Denis GUIMARD, Paris (FR); Johann SKOLSKI, Paris (FR)

(73) Assignee: SAINT-GOBAIN GLASS FRANCE, Courbevoie (FR)

(21) Appl. No.: 16/335,534

(22) PCT Filed: Sep. 25, 2017
(86) PCT No.: PCT/FR2017/052569

§ 371 Date: Mar. 21, 2019

(30) Foreign Application Priority Data
Sep. 26, 2016 (FR) 1659025

(51) Int. Cl. C03C 17/36; C23C 14/06; C23C 14/08; C23C 14/18; C23C 14/00; C23C 14/35

(52) U.S. Cl. CPC C03C 17/366; C23C 14/0652; C23C 14/083; C23C 14/086; C23C 14/185; C03C 2218/156; C03C 17/3626; C03C 17/3644; C23C 14/0036; C23C 14/352; C03C 2218/155; C03C 17/3618

(57) ABSTRACT

A material includes a substrate coated, on at least one face, with a coating including a first dielectric layer, a wetting layer, a silver layer and a second dielectric layer. At least one of the first and second dielectric layers is an oxide-based dielectric layer and an oxygen barrier layer is positioned between the oxide-based dielectric layer and the wetting layer. A process for obtaining such a material includes a stage of laser annealing of the coating.

The invention relates to the field of thin inorganic layers, in particular deposited on glass substrates. It more particularly relates to a process for obtaining a material comprising a substrate coated on at least one face with a stack of thin low-e layers.

Numerous thin layers are deposited on substrates, in particular made of flat or slightly bent glass, in order to confer specific properties on the materials obtained: optical properties, for example of reflection or of absorption of radiation of a range of given wavelengths, specific electrical conduction properties, or also properties related to the ease of cleaning or to the possibility for the material of self-cleaning.

A process commonly employed on the industrial scale for the deposition of thin layers, in particular on a glass substrate, is the magnetic-field-assisted cathode sputtering process, also known as the “magnetron” process. In this process, a plasma is created under high vacuum in the vicinity of a target comprising the chemical elements to be deposited. The active entities of the plasma, on bombarding the target, tear off said elements, which are deposited on the substrate, forming the desired thin layer. This process is termed “reactive” when the layer consists of a material resulting from a chemical reaction between the elements torn from the target and the gas present in the plasma. The major advantage of this process lies in the possibility of depositing, on one and the same line, a very complex stack of layers by causing the substrate to successively progress forward under different targets, this being done generally in one and the same device.

These thin layers are generally based on inorganic compounds: oxides, nitrides or also metals. Their thickness generally varies from a few nanometers to a few hundred nanometers, hence their description as “thin”.

The most advantageous include thin layers based on metallic silver, which have properties of electrical conduction and of reflection of infrared radiation, hence their use in solar-control glazings, in particular solar-protection glazings (targeted at reducing the amount of incoming solar energy) and/or low-emissivity glazings (targeted at reducing the amount of energy dissipated toward the outside of a building or of a vehicle).

In order in particular to avoid oxidation of the silver and to limit its properties of reflection in the visible region, the or each silver layer is generally inserted in a stack of layers. In the case of solar-control or low-emissivity glazings, the or each thin silver-based layer is generally positioned between two thin dielectric layers based on oxide or on nitride (for example made of TiO₂, SnO₂ or Si₃N₄). It is also possible to position, under the silver layer, a very thin layer intended to promote the wetting and the nucleation of the silver (for example made of zinc oxide ZnO) and, on the silver layer, a second very thin layer (a sacrificial layer, for example made of titanium) intended to protect the silver layer in the case where the deposition of the subsequent layer is carried out in an oxidizing atmosphere or in the case of heat treatments resulting in a migration of oxygen within the stack. These layers are respectively known as wetting layer and blocker layer.

The silver layers exhibit the distinguishing feature of experiencing an improvement in some of their properties when they are in an at least partially crystallized state. It is generally desired to maximize the degree of crystallization of these layers (the proportion of crystallized material by weight or by volume) and the size of the crystalline grains (or the size of the coherent diffraction domains measured by X-ray diffraction methods). It is known in particular that the silver layers exhibiting a high degree of crystallization and consequently a low content of nanometric grains exhibit a lower emissivity and a lower resistivity and also a higher transmission in the visible region than predominantly nanocrystallized silver layers. The electrical conductivity and the low-emissivity properties of these layers are thus improved. This is because the increase in the size of the grains is accompanied by a decrease in the grain boundaries, which is favorable to the mobility of the electrical charge carriers.

The silver layers deposited by a magnetron process are generally predominantly, indeed even completely, nanocrystallized (the mean size of the crystalline grains being less than a few nanometers) and heat treatments prove to be necessary in order to obtain the desired degree of crystallization or the desired grain size.

It is known to carry out a local and rapid laser annealing of coatings comprising one or more silver layers. To do this, the substrate with the coating to be annealed is caused to progress forward under a laser line, or else a laser line is caused to progress forward above the substrate carrying the coating. Laser annealing makes it possible to heat thin coatings to high temperatures, of the order of several hundred degrees, while preserving the underlying substrate. The rates of forward progression are of course preferably as high as possible, advantageously at least several meters per minute. The choice of the appropriate rate of forward progression results from a compromise between productivity, on the one hand, and effectiveness of the treatment, on the other hand. This is because the slower the rate of forward progression, the greater the amount of energy absorbed by the coating and the better will be the crystallization of the silver layer or layers.

In order to obtain suitable deposition rates, the thin dielectric layers based on oxides are generally deposited by a reactive magnetron process, starting from a target made of metal or of substoichiometric oxide, in an oxygen-containing plasma. The process parameters are then generally adjusted so as to obtain the desired oxide in a stoichiometric proportion. However, it is not unusual, as a result of a fluctuation in these parameters during the deposition process, for the layer of oxide deposited to be able to exhibit a substoichiometric composition. It has been observed that, in this case, the gain in resistivity of the silver layers after laser annealing was not as good as expected. This is because, beyond a certain threshold of rate of forward progression, the gain in resistivity can have a tendency to decrease with the decrease in the rate of forward progression, whereas the gain should, on the contrary, increase.

It is an aim of the invention to provide a process which makes it possible to overcome the abovementioned disadvantages. To this end, a subject matter of the invention is a process for obtaining a material comprising a substrate coated, on at least one face, with a stack of thin layers, comprising the following stages:
a stack of thin layers comprising a first dielectric layer, a wetting layer, a silver layer and a second dielectric layer is deposited on at least one face of said substrate,
the at least one coated face is heat treated using at least one laser radiation emitting in at least one wavelength between 100 and 2000 nm, preferably so that the sheet resistance of the stack is reduced by at least 5%;
   characterized in that at least one of said first and second dielectric layers is an oxide-based dielectric layer and in that an oxygen barrier layer is positioned between the oxide-based dielectric layer and the wetting layer. In particular, the first dielectric layer is a dielectric layer based on substoichiometric oxide and an oxygen barrier layer is positioned between the first dielectric layer and the wetting layer. The second dielectric layer can also be an oxide-based dielectric layer, in particular based on substoichiometric oxide. In this case, a second oxygen barrier layer can be positioned between the second dielectric layer and the wetting layer.

This is because, without wishing to be committed to any one theory, it is assumed that, when the oxide-based dielectric layer is substoichiometric in oxygen, this tends to reduce the surrounding layers by “pumping” the oxygen from the surrounding layers, in particular from the wetting layer, under the effect of the laser annealing. This would have the effect of detrimentally affecting the wetting layer on which the silver layer crystallizes and of consequently damaging the quality of the silver layer. The presence of an oxygen barrier layer between the oxide-based dielectric layer and the wetting layer makes it possible to prevent this phenomenon. This is because the oxygen barrier layer protects the wetting layer by preventing the migration of the oxygen toward the first dielectric layer.

The substrate is preferably a sheet of glass, of glass-ceramic or of a polymeric organic material. It is preferably transparent, colorless (it is then a clear or extra-clear glass) or colored, for example blue, green, gray or bronze. The glass is preferably of soda-lime-silica type but it can also be a glass of borosilicate or alumino-borosilicate type. The preferred polymeric organic materials are polycarbonate or polymethyl methacrylate or also polyethylene terephthalate (PET). The substrate advantageously exhibits at least one dimension greater than or equal to 1 m, indeed even 2 m and even 3 m. The thickness of the substrate generally varies between 0.5 mm and 19 mm, preferably between 0.7 and 9 mm, in particular between 2 and 8 mm, indeed even between 4 and 6 mm. The substrate can be flat or bent, indeed even flexible.

The glass substrate is preferably of the float glass type, that is to say capable of having been obtained by a process which consists in pouring the molten glass onto a bath of molten tin (“float” bath). In this case, the layer to be treated can be deposited both on the “tin” face and on the “atmosphere” face of the substrate. The terms “atmosphere” and “tin” faces are understood to mean the faces of the substrate which have respectively been in contact with the atmosphere prevailing in the float bath and in contact with the molten tin. The tin face contains a small superficial amount of tin which has diffused into the structure of the glass. The glass substrate can also be obtained by rolling between two rolls, a technique which makes it possible in particular to print patterns at the surface of the glass.

The term “clear glass” is understood to mean a soda-lime-silica glass obtained by floating which is not coated with layers and which exhibits a light transmission of the order of 90%, a light reflection of the order of 8% and an energy transmission of the order of 8% and an energy transmission of the order 83%, for a thickness of 4 mm. The light and energy transmissions and reflections are as defined by the standard NF EN 410. Typical clear glasses are, for example, sold under the name SGG Planilux by Saint-Gobain Glass France or under the name Planibel Clair by AGC Flat Glass Europe. These substrates are conventionally employed in the manufacture of low-e glazings.

The process according to the invention is very obviously not limited to the depositions carried out on a clear glass substrate or on a substrate with a thickness of 4 mm. The coating can be deposited on any type of substrate but the absorption of the stack as defined according to the invention is regarded as having been deposited on a clear glass substrate, the thickness of which is 4 mm.

The stack of thin layers is preferably deposited by cathode sputtering. It successively comprises, starting from the substrate, a first dielectric layer, a wetting layer, a silver layer and a second dielectric layer, at least one of said first and second dielectric layers being an oxide-based dielectric layer, and an oxygen barrier layer is positioned between the oxide-based dielectric layer and the wetting layer.

The oxygen barrier layer makes it possible to prevent the migration of oxygen from the wetting layer toward the oxide-based dielectric layer during the heat treatment according to the invention. When the first dielectric layer is an oxide-based dielectric layer, the oxygen barrier layer is positioned below the wetting layer, preferably in direct contact with the wetting layer. When the second dielectric layer is an oxide-based dielectric layer, the oxygen barrier layer is positioned above the silver layer, preferably in direct contact with the second oxide-based dielectric layer.

In the present patent application, the terms “below” and “above” associated with the position of a first layer with respect to a second layer mean that the first layer is closer to, respectively further from, the substrate than the second layer. However, these terms do not rule out the presence of other layers between said first and second layers. On the contrary, a first layer “in direct contact” with a second layer means that no other layer is positioned between these. It is the same for the expressions “directly above” and “directly below”. Thus, it is understood that, unless it is indicated otherwise, other layers may be inserted between each of the layers of the stack.

The oxygen barrier layer is preferably a layer based on silicon nitride, on silicon oxynitride, on silicon carbide, on silicon oxycarbide, on aluminum nitride or on titanium carbide. More preferably, the oxygen barrier layer is a layer based on silicon nitride. Generally, the silicon nitride can be doped, for example with aluminum or boron, in order to facilitate its deposition by cathode sputtering techniques. The degree of doping (corresponding to the atomic percentage with respect to the amount of silicon) generally does not exceed 2%. The oxygen barrier layer generally exhibits a thickness of 1 to 30 nm, preferably at least 3, 4, indeed even 5, nm, and at most 20 nm, indeed even at most 15 nm or even 10 nm.

The expression “dielectric layer” within the meaning of the present invention denotes a nonmetallic layer, that is to say a layer which does not consist of metal. This expression denotes in particular a layer consisting of a material, the ratio of the refractive index to the extinction coefficient (n/k) of which over the whole of the wavelength range of the visible region (from 380 nm to 780 nm) is equal to or greater than 5.

The oxide-based dielectric layer is generally substoichiometric, that is to say that the proportion of oxygen is less than that of the stable form of the oxide under consideration. For example, for an oxide of a divalent metal of stable formula MO, a substoichiometric oxide can be defined by the formula MOₓ, with x between 0.6 and 0.99, preferably between 0.8 and 0.99; for a trivalent metal oxide of stable formula M₂O₃, a substoichiometric oxide can be defined by the formula M₂Oₓ, with x between 2 and 2.99, preferably between 2.6 and 2.99; for an oxide of a tetravalent metal of stable formula MO₂, a substoichiometric oxide can be defined by the formula MOₓ, with x between 1.5 and 1.99, preferably between 1.8 and 1.99; for a pentavalent metal oxide of stable formula M₂O₅, a substoichiometric oxide can be defined by the formula M₂Oₓ, with x between 3.5 and 4.99, preferably between 4 and 4.99; for a hexavalent metal oxide of stable formula MO₃, a substoichiometric oxide can be defined by the formula MOₓ, with x between 2 and 2.99, preferably between 2.6 and 2.99. It can, for example, be a layer based on titanium, silicon, niobium or magnesium oxide. The oxide-based dielectric layer is preferably a titanium oxide layer, in particular a layer of substoichiometric titanium oxide TiOₓ (x then being strictly less than 2). According to a specific embodiment, the value of x is preferably less than or equal to 1.8, in particular between 1.5 and 1.8. In this case, the dielectric layer participates in the absorption of the laser radiation, which thus makes it possible to improve the crystallization of the silver layer and/or to increase the rate of forward progression during the heat treatment, and thus the productivity. According to another specific embodiment, the first dielectric layer is a layer of slightly substoichiometric titanium oxide, that is to say that the value x is greater than or equal to 1.8, preferably greater than 1.9. This is because it is not unusual for the process parameters, although initially set to deposit a layer of stoichiometric TiO₂ (for the sake in particular of reducing the residual absorption of the stack), to be able to fluctuate during the production so that the layer actually deposited is slightly substoichiometric.

The other dielectric layer (that of the first or second dielectric layer which is not necessarily based on oxide) can be based on oxide, optionally substoichiometric oxide, in particular made of titanium oxide, tin oxide, silicon oxide or their mixtures, or on nitride, in particular made of silicon nitride.

In a specific embodiment, each of the first and second dielectric layers is an oxide-based layer, especially a layer based on titanium oxide, in particular a layer of substoichiometric titanium oxide TiOₓ as defined above. In this case, the stack according to the invention can comprise two oxygen barrier layers, respectively between the wetting layer and each of the first and second dielectric layers. According to this embodiment, the stack successively comprises, starting from the substrate, a first oxide-based dielectric layer, a first oxygen barrier layer, a wetting layer, a silver layer, a second oxygen barrier layer and a second oxide-based dielectric layer.

The first and second dielectric layers generally each have a thickness of 10 to 60 nm, preferably 15 to 50 nm.

The stack according to the invention can comprise an overblocker and/or underblocker layer respectively above or below the or each silver layer and in direct contact with the latter. The blocker (underblocker and/or overblocker) layers are generally based on a metal chosen from nickel, chromium, titanium or niobium or on an alloy of these different metals. Mention may in particular be made of nickel/titanium alloys (in particular those comprising approximately 50% by weight of each metal) or nickel/chromium alloys (in particular those comprising 80% by weight of nickel and 20% by weight of chromium). The overblocker layer can also consist of several superimposed layers, for example, on moving away from the substrate, of titanium and then of a nickel alloy (in particular a nickel/chromium alloy), or vice versa. These blocker (underblocker and/or overblocker) layers are very thin, normally with a thickness of less than 1 nm, so as not to affect the light transmission of the stack, and are capable of being partially oxidized during the heat treatment according to the invention. Generally, the blocker layers are sacrificial layers capable of capturing oxygen originating from the atmosphere or from the substrate, thus preventing the silver layer from oxidizing.

The wetting layer is generally based on zinc oxide. It preferably consists of zinc oxide, optionally doped with aluminum. The wetting layer is generally positioned below the silver layer and in direct contact with the latter or, when a blocker layer is present, in direct contact with the blocker layer. It generally has a thickness of 2 to 10 nm, preferably of 3 to 8 nm.

The stack can comprise one or more silver layers, in particular two or three silver layers. When several silver layers are present, the general architecture presented above can be repeated. In this case, the second dielectric layer relative to a given silver layer (thus located above this silver layer) generally coincides with the first dielectric layer relative to the following silver layer. Preferably, the physical thickness of the or each silver layer is between 6 and 20 nm.

The stack can comprise other layers, in particular between the substrate and the first dielectric layer, directly above the silver (or overblocker) layer, or also above the second dielectric layer.

An adhesion layer can in particular be positioned directly above the silver layer or, if present, directly above the overblocker layer, in order to improve the adhesion between the silver or overblocker layer and the upper layers. The adhesion layer can, for example, be a layer of zinc oxide, in particular doped with aluminum, or also a layer of tin oxide. It generally has a thickness of 2 to 10 nm.

The first dielectric layer is preferably deposited directly above the substrate. In order to adapt the optical properties of the stack (in particular the appearance in reflection) as best as possible, an underlayer can alternatively be positioned between the first dielectric layer and the substrate, preferably in direct contact with these. This underlayer can be a layer based on oxide or on nitride, in particular on silicon nitride optionally doped with aluminum. It generally has a thickness of 2 to 30 nm, preferably 3 to 20 nm, indeed even 5 to 15 nm.

An oxygen-donating layer can also be positioned below or below the or each oxide-based dielectric layer. The term “oxygen-donating layer” is understood to mean an oxide-based layer which is capable of donating oxygen to the oxide-based dielectric layer, in particular during the heat treatment. The presence of an oxygen-donating layer makes it possible to improve the oxidation of the oxide-based dielectric layer, in particular when the latter is substoichiometric, and to thus limit the residual light absorption of the stack. The oxygen-donating layer is typically based on an oxide, the redox potential of which is less than the material of the wetting layer, which is preferably zinc oxide. It can, for example, be a layer of tin oxide or of mixed oxide of tin and of zinc SnₓZn_{y}O with an atomic content of tin of 0.3≤x<1.0 and x+y=1; indeed even 0.5≤x<1.0 and x+y=1. The oxygen-donating layer can be oxidized according to the stable stoichiometry or optionally substoichiometric in oxygen. The oxygen-donating layer generally has a thickness of 1 to 30 nm, preferably of 3 to 50 nm.

A protective layer can be positioned on the second dielectric layer. This protective layer generally constitutes the final layer of the stack and is intended in particular to protect the stack from any mechanical (scratches, and the like) or chemical attacks. It can be a layer based on oxide or on nitride, in particular on silicon nitride.

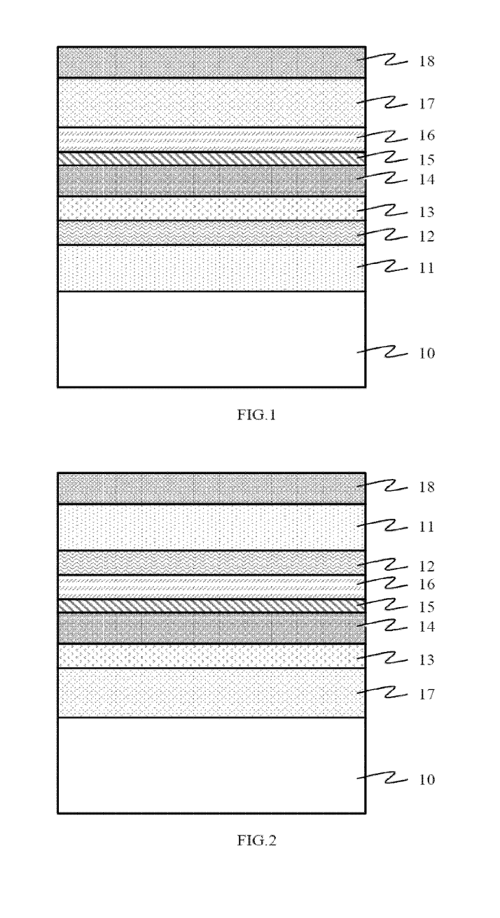

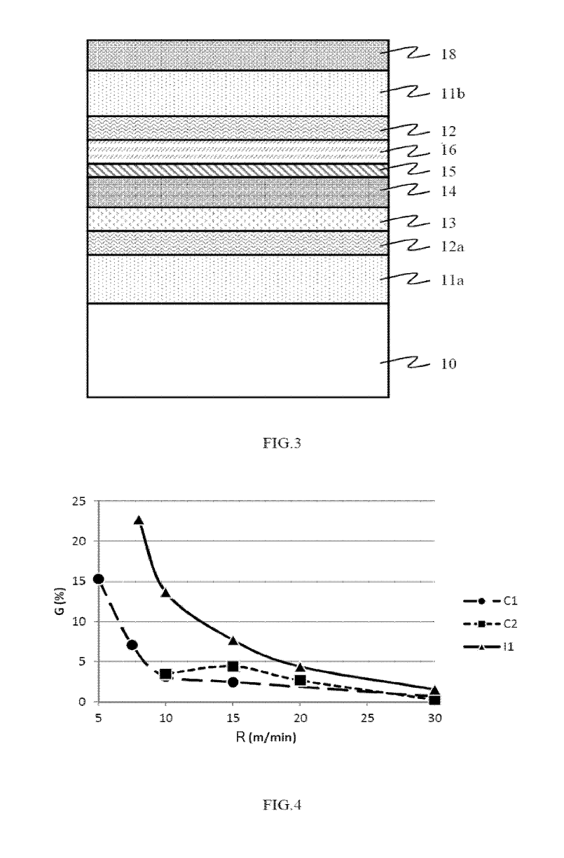

The protective layer generally has a thickness of 3 to 50 nm. FIGS. 1 to 3 illustrate examples of a stack according to the invention. In a first embodiment illustrated by FIG. 1, the stack successively comprises, starting from the substrate 10, a first oxide-based dielectric layer 11, an oxygen barrier layer 12, a wetting layer 13, a silver layer 14, optionally a blocker layer 15, optionally an adhesion layer 16, a second dielectric layer 17 and optionally a protective layer 18. In a second embodiment illustrated by FIG. 2, the stack successively comprises, starting from the substrate 10, a first dielectric layer 17, a wetting layer 13, a silver layer 14, optionally a blocker layer 15, optionally an adhesion layer 16, an oxygen barrier layer 12, a second oxide-based dielectric layer 11 and optionally a protective layer 18. In a third embodiment illustrated by FIG. 3, the stack successively comprises, starting from the substrate 10, a first oxide-based dielectric layer 11a, a first oxygen barrier layer 12a, a wetting layer 13, a silver layer 14, optionally a blocker layer 15, optionally an adhesion layer 16, a second oxygen barrier layer 12b, a second oxide-based dielectric layer 11b and optionally a protective layer 18.

Examples of a stack according to the invention can be chosen from:

Substrate//TiOₓ/Si₃N₄/ZnO/Ag/Ti/ZnO/TiO₂/Si₃N₄

Substrate//TiOₓ/Si₃N₄/ZnO/Ti/Ag/Ti/ZnO/TiO₂/Si₃N₄

Substrate//TiO₂/ZnO/Ag/Ti/ZnO/Si₃N₄/TiOₓ/Si₃N₄

Substrate//TiO₂/ZnO/Ti/Ag/Ti/ZnO/Si₃N₄/TiOₓ/Si₃N₄

Substrate//TiOₓ/Si₃N₄/ZnO/Ag/Ti/ZnO/Si₃N₄/TiOₓ/Si₃N₄

Substrate//TiOₓ/Si₃N₄/ZnO/Ti/Ag/Ti/ZnO/Si₃N₄/TiOₓ/Si₃N₄

The process according to the invention also comprises a stage of heat treatment using a laser. This heat treatment makes it possible to contribute sufficient energy to promote the crystallization of the thin silver layer by a physicochemical mechanism of crystal growth around seeds already present in the layer, while remaining in the solid phase. The fact of promoting the crystallization of the silver layer can in particular be reflected by a disappearance of the possible amorphous phase residues and/or by an increase in the size of the coherent diffraction domains and/or by a decrease in the density of point defects (gaps, interstitial atoms) or of surface or bulk defects, such as twin crystals.

The process according to the invention exhibits the advantage of heating only the low-e stack, without significant heating of the whole of the substrate. It is thus no longer necessary to carry out a slow and controlled cooling of the substrate before cutting up or storing the glass.

The use of laser radiation exhibits the advantage of obtaining temperatures generally of less than 100° C. and even often of less than 50° C. on the face opposite the first face of the substrate (that is to say, on the uncoated face). This particularly advantageous characteristic is due to the fact that the heat exchange coefficient is very high, typically greater than 400 W/(m².$). The power per unit area of the laser radiation at the stack to be treated is even preferably greater than or equal to 10, indeed even 20 or 30 kW/cm².

This very high energy density makes it possible, at the stack, to extremely rapidly (generally in a time of less than or equal to 1 second) achieve the temperature desired and consequently to accordingly limit the duration of the treatment, the heat generated then not having the time to diffuse within the substrate. Thus, each point of the stack is preferably subjected to the treatment according to the invention (and in particular brought to a temperature of greater than or equal to 300° C.) for a period of time generally of less than or equal to 1 second, indeed even 0.5 second.

By virtue of the very high heat exchange coefficient associated with the process according to the invention, the portion of the glass located at 0.5 mm from the thin layer is generally not subjected to temperatures of greater than 100° C. The temperature of the face of the substrate opposite the face treated by the at least one laser radiation preferably does not exceed 100° C., in particular 50° C. and even 30° C. during the heat treatment.

Most of the energy contributed is thus “used” by the stack in order to improve the crystallization characteristics of the or of each silver layer which it contains.

This process also makes it possible to incorporate a laser treatment device on the existing continuous production lines. The laser can thus be incorporated in a line for the deposition of layers, for example a line for deposition by magnetic-field-assisted cathode sputtering (magnetron process). In general, the line comprises devices for handling the substrates, a deposition unit, optical control devices and stacking devices. The substrates progress forward, for example on conveyor rollers, successively in front of each device or each unit. The laser is preferably located immediately after the unit for deposition of layers, for example at the outlet of the deposition unit. The coated substrate can thus be treated in line after the layers have been deposited, at the outlet of the deposition unit and before the optical control devices, or after the optical control devices and before the devices for stacking the substrates. It is also possible, in some cases, to carry out the heat treatment according to the invention within even the vacuum deposition chamber. The laser is then incorporated in the deposition unit. For example, the laser can be introduced into one of the chambers of a cathode sputtering deposition unit.

Whether the laser is outside the deposition unit or incorporated in it, these “in-line” or “continuous” processes are preferable to a process involving off-line operations, in which it would be necessary to stack the glass substrates between the deposition stage and the heat treatment.

However, processes involving off-line operations can have an advantage in the cases where the heat treatment according to the invention is carried out in a place different from that where the deposition is carried out, for example in a place where the conversion of the glass is carried out. The radiation device can thus be incorporated in other lines than the line for deposition of layers. For example, it can be incorporated in a line for the manufacture of multiple glazings (in particular double or triple glazings) or in a line for the manufacture of laminated glazings. In these different cases, the heat treatment according to the invention is preferably carried out before the multiple or laminated glazing is produced.

The laser radiation preferably results from at least one laser beam forming a line (known as “laser line” in the continuation of the text) which simultaneously irradiates the entire width of the substrate. The in-line laser beam can in particular be obtained using focusing optical systems. In order to be able to simultaneously irradiate very wide substrates (>3 m), the laser line is generally obtained by combining several individual laser lines. The thickness of the individual laser lines is preferably between 0.01 and 1 mm. Their length is typically between 5 mm and 1 m. The individual laser lines are generally juxtaposed side-by-side in order to form a single laser line in such a way that the entire surface of the stack is treated. Each individual laser line is preferably positioned perpendicularly to the direction of forward progression of the substrate.

The laser sources are typically laser diodes or fiber lasers, in particular fiber, diode or also disk lasers. Laser diodes make it possible to economically achieve high power densities, with respect to the electrical supply power, for a small space requirement. The space requirement of fiber lasers is even smaller, and the linear power density obtained can be even higher, for a cost, however, which is greater. The term “fiber lasers” is understood to mean lasers in which the place where the laser radiation is generated is spatially removed from the place to which it is delivered, the laser radiation being delivered by means of at least one optical fiber. In the case of a disk laser, the laser radiation is generated in a resonator cavity in which the emitting medium, which is in the form of a disk, for example a thin disk (approximately 0.1 mm thick) made of Yb:YAG, is found. The radiation thus generated is coupled in at least one optical fiber directed toward the place of treatment. The laser can also be a fiber laser, insofar as the amplification medium is itself an optical fiber. Fiber or disk lasers are preferably optically pumped using laser diodes. The radiation resulting from the laser sources is preferably continuous.

The wavelength of the laser radiation, and thus the treatment wavelength, is preferably within a range extending from 500 to 1300 nm, in particular from 800 to 1100 nm. High-power laser diodes which emit at one or more wavelengths chosen from 808 nm, 880 nm, 915 nm, 940 nm or 980 nm have proved to be particularly well suited. In the case of a disk laser, the treatment wavelength is, for example, 1030 nm (emission wavelength for a Yb:YAG laser). For a fiber laser, the treatment wavelength is typically 1070 nm.

Preferably, the absorption of the stack at the wavelength of the laser radiation is greater than or equal to 5%, preferably greater than 10% or 15%, indeed even greater than 20% or even 30%. The absorption is defined as being equal to the value of 100%, from which the transmission and the reflection of the layer are subtracted.

In order to treat the entire surface of the coated substrate, a relative displacement is created between, on the one hand, the substrate coated with the layer and the laser line. The substrate can thus be displaced, in particular in translational forward progression, in comparison with the stationary laser line, generally below but optionally above the laser line. This embodiment is particularly appreciable for a continuous treatment. Preferably, the rate of forward progression, that is to say the difference between the respective rates of the substrate and the laser, is greater than or equal to 1 m/min, indeed even greater than 2, 3, 4 or 5 m/min, or even advantageously greater than or equal to 8 or 10 m/min, this being the case in order to provide a high treatment rate.

The substrate can be moved using any mechanical conveying means, for example using belts, rollers or trays moving translationally. The conveying system makes it possible to control and regulate the rate of the displacement. If the substrate is made of flexible polymeric organic material, it can be displaced using a film advance system in the form of a sequence of rollers.

Of course, all the relative positions of the substrate and of the laser are possible, as long as the surface of the substrate can be suitably irradiated. Usually, the substrate will be positioned horizontally but it can also be positioned vertically or according to any possible inclination. When the substrate is positioned horizontally, the laser is generally positioned so as to irradiate the upper face of the substrate. The laser can also irradiate the lower face of the substrate. In this case, it is necessary for the support system for the substrate, optionally the system for conveying the substrate when the latter is moving, to allow the radiation to pass in the zone to be irradiated. This is the case, for example, when conveying rollers are used: since the rollers are separate entities, it is possible to position the laser in a zone located between two successive rollers.

The present invention also relates to a material comprising a substrate coated with a low-e coating as described above. The material according to the invention is capable of being obtained by the process according to the invention. The material according to the invention is preferably incorporated in a glazing. The present invention thus also relates to a glazing comprising a material comprising a substrate coated with a low-e coating as described above. The glazing can be single or multiple (in particular double or triple), insofar as it can comprise several glass sheets bringing about a gas-filled space. The glazing can also be laminated and/or tempered and/or hardened and/or bent.

The invention is illustrated with the help of the following nonlimiting exemplary embodiments.

### EXAMPLES

Different low-e stacks are deposited on a clear glass substrate with a thickness of 4 mm sold under the name SGG Planilux by the applicant company. All the stacks are deposited, in a known way, on a (magnetron process) cathode sputtering line in which the substrate progresses forward under different targets.

Table 1 shows, for each stack tested, the physical thicknesses of the layers, expressed in nm. The first line corresponds to the layer furthest from the substrate, in contact with the open air. The sample C1 comprises a first dielectric layer made of standard titanium oxide TiO₂, while the samples C2 and I1 comprise a first dielectric layer made of titanium oxide deficient in oxygen TiOₓ. The sample I1 additionally comprises an oxygen barrier layer made of silicon nitride Si₃N₄:Al between the first dielectric layer and the wetting layer made of zinc oxide.

TABLE 1

| Sample | C1 | C2 | I1 |
|---|---|---|---|
| Si₃N₄: Al | 30 | 30 | 30 |
| TiO₂ | 15 | 15 | 15 |
| ZnO: Al | 4 | 4 | 4 |
| Ti | 0.75 | 0.75 | 0.75 |
| Ag | 13.7 | 13.7 | 13.7 |
| ZnO: Al | 4 | 4 | 4 |
| Si₃N₄: Al | — | — | 5 |
| TiO₂ | 27 | — | — |
| TiOₓ | — | 27 | 27 |

The parameters for the deposition which are employed for the different layers are summarized in table 2 below.

TABLE 2

| | | Deposition | | |
|---|---|---|---|---|
| Layer | Target employed | pressure | | Gas |
| Si₃N₄ | Si: Al 8% | 1.5 | μbar | Ar 22 sccm/N₂ 22 sccm |
| TiO₂ | TiOₓ deficient in | 1.5 | μbar | Ar 30 sccm/O₂ 6 sccm |
| | oxygen | | | |
| TiOₓ | TiOₓ deficient in | 1.5 | μbar | Ar 30 sccm |
| | oxygen | | | |
| ZnO: Al | AZO 2 wt % Al₂O₃ | 1.5 | μbar | Ar 20 sccm/O₂ 2 sccm |
| Ti | Ti | 8 | μbar | Ar 180 sccm |
| Ag | Ag | 8 | μbar | Ar 180 sccm |

The samples are treated using an in-line laser, obtained by juxtaposition of several individual lines, emitting a 50% 915 nm and 50% 980 nm radiation with a power of 56 kW/cm², in comparison with which the coated substrate progresses forward translationally. The samples were treated at different rates of forward progression.

For each sample, the sheet resistance was measured before and after heat treatment. The sheet resistance (Rs) was measured by a non-contact measurement by induction using an SRM-12 device sold by Nagy. The gain G in sheet resistance is defined by G=(Rs_{before}−Rs_{after})/RS_{before}. A gain of 5% thus corresponds to a decrease in the sheet resistance of 5%.

FIG. 4 shows, for each sample, the gain (G) in sheet resistance of the stack after heat treatment as a function of the treatment rate (R). The greater the gain, the more effective the heat treatment. Thus, it may be pointed out that, on the one hand, by comparison of the samples I1 and C2, the presence of the oxygen barrier layer in the sample I1 makes it possible to prevent the loss of effectiveness of the laser annealing when the first dielectric layer is deficient in oxygen and, on the other hand, by comparison of the samples I1 and C1, that the combination of a first dielectric layer deficient in oxygen and of an oxygen barrier layer in the sample I1 makes it possible to improve the effectiveness of the laser annealing or, at an equivalent gain, to increase the treatment rate. This advantage can be attributed to the fact that the layer of titanium oxide deficient in oxygen is more absorbing than a standard layer at the wavelength of the laser.

1. A process for obtaining a material comprising a substrate coated, on at least one face, with a stack of thin layers, comprising the following stages:
depositing a stack of thin layers comprising a first dielectric layer, a wetting layer, a silver layer and a second dielectric layer on at least one face of said substrate,
heat treating said at least one coated face using at least one laser radiation emitting in at least one wavelength between 100 and 2000 nm;
wherein said first dielectric layer is a dielectric layer based on substoichiometric oxide and in that an oxygen barrier layer is positioned between the first dielectric layer and the wetting layer.

2. The process as claimed in claim 1, wherein the treatment thermally is carried out so that the sheet resistance of the stack is decreased by at least 5%.

3. The process as claimed in claim 1, wherein the substrate is a glass sheet.

4. The process as claimed in claim 1, wherein the wetting layer is a layer based on zinc oxide.

5. The process as claimed in claim 1, wherein the oxygen barrier layer is positioned directly above the first dielectric layer.

6. The process as claimed in claim 1, wherein each of the first and second dielectric layers is an oxide-based dielectric layer.

7. The process as claimed in claim 6, wherein a first oxygen barrier layer is positioned between the first dielectric layer and the wetting layer and a second oxygen barrier layer is positioned between the second dielectric layer and the wetting layer.

8. The process as claimed in claim 7, wherein the second oxygen barrier layer is positioned directly below the second dielectric layer.

9. The process as claimed in claim 1, wherein the oxygen barrier layer is chosen from a layer based on silicon nitride, on silicon oxynitride, on silicon carbide, on silicon oxycarbide, on aluminum nitride or on titanium carbide.

10. The process as claimed in claim 1, wherein the oxygen barrier layer has a thickness of 1 to 30 nm.

11. The process as claimed in claim 1, wherein the first dielectric layer based on substoichiometric oxide is a layer based on titanium, silicon, niobium or magnesium oxide.

12. The process as claimed in claim 1, wherein the first dielectric layer based on substoichiometric oxide is a layer of substoichiometric titanium oxide TiOₓ.

13. The process as claimed in claim 12, wherein x is less than or equal to 1.8.

14. A material comprising:
a substrate coated with a stack of thin layers successively comprising a first dielectric layer, a wetting layer, a silver layer and a second dielectric layer,
wherein said first dielectric layer is a dielectric layer based on sub stoichiometric oxide and an oxygen barrier layer is positioned between the dielectric layer based on substoichiometric oxide and the wetting layer.
